(19) United States
(12) Patent Application Publication
(10) Pub. No.: US 2023/0070416 A1
(43) Pub. Date: Mar. 9, 2023

(54) DISPLAY DEVICE USING SEMICONDUCTOR LIGHT-EMITTING ELEMENTS AND METHOD OF MANUFACTURING SAME

(71) Applicant: LG ELECTRONICS INC., Seoul (KR)

(72) Inventor: Taein KWON, Seoul (KR)

(73) Assignee: LG ELECTRONICS INC., Seoul (KR)

(21) Appl. No.: 17/799,076

(22) PCT Filed: Feb. 19, 2020
(86) PCT No.: PCT/KR2020/002380

§ 371 Date: Aug. 11, 2022

(51) Int. Cl. H01L 33/00; H01L 27/15

(52) U.S. Cl. CPC H01L 33/005; H01L 27/156

(57) ABSTRACT

The present invention relates to a display device and a method of manufacturing same, and more particularly, to a display device using semiconductor light-emitting elements each having a size that is several to several tens of um, and to a method of manufacturing same. The present invention provides a display device comprising a substrate including a wiring electrode, and a plurality of semiconductor light-emitting elements electrically connected to the wiring electrode, wherein each of the semiconductor light-emitting elements is provided with a plurality of recessed portions formed on a side surface thereof, and at least one of inner walls of each of the recessed portions forms an inclination with respect to one surface of a semiconductor light-emitting element that is in contact with the substrate.

### TECHNICAL FIELD

The present disclosure relates to a display device and a method of manufacturing the same, and more particularly, to a display device using a semiconductor light-emitting element having a size of several μm to several tens of μm and a method of manufacturing the same.

### BACKGROUND ART

In recent years, liquid crystal displays (LCDs), organic light-emitting diode (OLED) displays, and micro-LED displays have been competed to implement a large-area display in the field of display technology.

On the other hand, when semiconductor light-emitting elements (micro-LED (μLED)) having a diameter or a cross sectional area of 100 microns or less are used in a display, the display may provide a very high efficiency because it does not absorb light using a polarizing plate or the like. However, since a large-sized display requires millions of semiconductor light-emitting elements, it has difficulty in transferring the devices compared to other technologies.

Technologies currently in development for transfer processes include pick & place, laser lift-off (LLO), self-assembly, or the like. Among them, the self-assembly method, which is a method in which the semiconductor light-emitting element locates themselves in a fluid, is the most advantageous method for realizing a large-sized display device.

In recent years, U.S. Pat. No. 9,825,202 proposed a micro-LED structure suitable for self-assembly, but there is not yet research on technologies for fabricating a display through self-assembly of micro-LEDs. Accordingly, the present disclosure proposes a new type of manufacturing method and apparatus in which micro-LEDs can be self-assembled.

### DISCLOSURE OF INVENTION

### Technical Problem

An aspect of the present disclosure is to provide a new fabrication process with high reliability in a large-screen display using micro-sized semiconductor light-emitting elements.

Another aspect of the present disclosure is to provide a structure capable of securing a high transfer yield even when a size of a semiconductor light-emitting element is reduced.

Still another aspect of the present disclosure is to provide a structure capable of securing a high transfer yield even when a strength of a magnetic force acting on a semiconductor light-emitting element is weakened.

### Solution to Problem

In order to achieve the objectives of the present disclosure, the present disclosure provides a display device including a substrate including a wiring electrode, and a plurality of semiconductor light-emitting elements electrically connected to the wiring electrode, wherein each of the semiconductor light-emitting elements is provided with a plurality of recessed portions formed on a side surface thereof, and at least one of inner walls of each of the recessed portions is formed to be inclined with respect to one surface of the semiconductor light-emitting element in contact with the substrate.

In an embodiment, each of the semiconductor light-emitting elements may include a first and a second conductive electrode, a first conductive semiconductor layer disposed on the substrate, an active layer deposited on a portion of the first conductive semiconductor layer, and a second conductive semiconductor layer disposed on the active layer, wherein the first conductive electrode is disposed on one surface on which the active layer is deposited between both surfaces of the first conductive semiconductor layer.

In an embodiment, each of the recessed portions may be formed on a side surface of the first conductive semiconductor layer.

In an embodiment, each of the semiconductor light-emitting elements may include a first and a second conductive electrode, a first conductive semiconductor layer disposed on the substrate, an active layer deposited on the first conductive semiconductor layer, and a second conductive semiconductor layer disposed on the active layer, wherein the first conductive electrode is disposed on one surface facing the substrate between both surfaces of the first conductive electrode, and the second conductive electrode is disposed on one surface facing a direction opposite to a direction facing the substrate between both surfaces of the second conductive electrode.

In an embodiment, each of the recessed portions may be formed on a side surface of each of the first conductive semiconductor layer, the active layer, and the second conductive semiconductor layer.

In an embodiment, each of the recessed portions may be formed to be inclined with respect to one surface of the semiconductor light-emitting element in contact with the substrate, and provided with a plurality of inclined surfaces disposed adjacent to one another.

In an embodiment, an angle between the inclined surface and one surface of the semiconductor light-emitting element in contact with the substrate may increase as a distance from the substrate increases.

In addition, the present disclosure provides a self-assembly method of semiconductor light-emitting elements, and the method may include manufacturing semiconductor light-emitting elements having a recessed portion on a side thereof, dispersing the semiconductor light-emitting elements in a fluid accommodated in a fluid chamber, transferring a substrate such that an assembly surface of the substrate is immersed in the fluid, transferring a magnet disposed on one side of the substrate along one direction to move the semiconductor light-emitting elements accommodated in the fluid chamber along the one direction, and applying power to a plurality of electrodes disposed on an assembly surface of the substrate to guide the semiconductor light-emitting elements to preset positions such that the semiconductor light-emitting elements are placed at the preset positions during the movement of the semiconductor light-emitting elements, wherein the applying of a magnetic force to the semiconductor light-emitting elements includes rotating the magnet to rotate the semiconductor light-emitting elements such that a lift force acts on each of the semiconductor light-emitting elements.

According to an embodiment, the manufacturing of semiconductor light-emitting elements having a recessed portion on a side thereof may include forming an epitaxial layer in which a first conductive semiconductor layer, an active layer, and a second conductive semiconductor layer are sequentially deposited on a growth substrate, depositing a photoresist layer in which a plurality of slits are continuously disposed on the second conductive semiconductor layer, and irradiating light onto the photoresist layer to form semiconductor light-emitting elements having a plurality of recessed portions on a side surface thereof, wherein the forming of the semiconductor light-emitting elements includes irradiating light to the continuously disposed slits to form a recessed portion including an inclined surface.

In an embodiment, the manufacturing of semiconductor light-emitting elements having a recessed portion on a side thereof may include forming an epitaxial layer in which a first conductive semiconductor layer, an active layer, and a second conductive semiconductor layer are sequentially deposited on a growth substrate, etching a portion of the layers deposited on the first conductive semiconductor layer such that a portion of the first conductive semiconductor layer is exposed to an outside, depositing a photoresist layer in which a plurality of slits are continuously disposed on the first conductive semiconductor layer exposed to the outside, and irradiating light onto the photoresist layer to form semiconductor light-emitting elements having a plurality of recessed portions on a side surface of the first conductive type semiconductor layer, wherein the forming of the semiconductor light-emitting elements includes irradiating light to the continuously disposed slits to form a recessed portion including an inclined surface.

### ADVANTAGEOUS EFFECTS OF INVENTION

According to the present disclosure having the foregoing configuration, a large number of semiconductor light-emitting elements may be assembled at one time in a display device in which individual pixels are formed with micro light-emitting diodes.

As described above, according to the present disclosure, a large number of semiconductor light-emitting elements may be pixelated on a wafer having a small size, and then transferred onto a large-area substrate. Through this, it may be possible to produce a large-area display device at a low cost.

Furthermore, according to the manufacturing method of the present disclosure, semiconductor light-emitting elements may be simultaneously transferred to exact positions using a magnetic field and an electric field in a solution, thereby allowing a low cost, high efficiency, and high-speed transfer implementation.

In addition, since assembly by an electric field is carried out, selective assembly may be allowed through a selective electrical application without any additional device or process. Moreover, an assembly substrate may be placed on an upper side of a chamber, thereby facilitating loading and unloading of the substrate, and preventing non-specific binding of the semiconductor light-emitting element.

As described above, according to the present disclosure, a lift force in a direction opposite to gravity acts on the semiconductor light-emitting element during self-assembly. Through this, the present disclosure minimizes tailing occurring when a magnetic force acting on the semiconductor light-emitting element is weakened.

### BRIEF DESCRIPTION OF DRAWINGS

FIG. 1 is a conceptual view showing a display device using a semiconductor light-emitting element according to an embodiment of the present disclosure.

FIG. 2 is a partially enlarged view showing a portion “A” of the display device in FIG. 1.

FIG. 3 is an enlarged view showing a semiconductor light-emitting element in FIG. 2.

FIG. 4 is an enlarged view showing another embodiment of the semiconductor light-emitting element in FIG. 2.

FIGS. 5A to 5E are conceptual views for explaining a new process of manufacturing the foregoing semiconductor light-emitting element.

FIG. 6 is a conceptual view showing an example of a self-assembly device of semiconductor light-emitting elements according to the present disclosure.

FIG. 7 is a block diagram showing the self-assembly device in FIG. 6.

FIGS. 8A to 8E are conceptual views showing a step of self-assembling semiconductor light-emitting elements using the self-assembly device in FIG. 6.

FIG. 9 is a conceptual view for explaining the semiconductor light-emitting element in FIGS. 8A to 8E.

FIG. 10 is a conceptual view showing a semiconductor light-emitting element that sinks to a bottom of a fluid chamber during self-assembly.

FIG. 11 is a perspective view showing a semiconductor light-emitting element according to an embodiment of the present disclosure.

FIG. 12 is a plan view showing a semiconductor light-emitting element according to an embodiment of the present disclosure.

FIG. 13 is a conceptual view showing a self-assembly method using a semiconductor light-emitting element according to the present disclosure.

FIG. 14A is a perspective view showing a flip-chip type semiconductor light-emitting element having a recessed portion.

FIG. 14B is a plan view showing a flip-chip type semiconductor light-emitting element having a recessed portion.

FIG. 15 is a perspective view showing a horizontal type semiconductor light-emitting element having a recessed portion.

FIGS. 16 to 21 are conceptual views showing a method of manufacturing a semiconductor light-emitting element included in a display device according to the present disclosure.

FIG. 22 is a conceptual view showing a process of forming a wiring electrode after self-assembly.

### MODE FOR THE INVENTION

Hereinafter, the embodiments disclosed herein will be described in detail with reference to the accompanying drawings, and the same or similar elements are designated with the same numeral references regardless of the numerals in the drawings and their redundant description will be omitted. A suffix “module” and “unit” used for constituent elements disclosed in the following description is merely intended for easy description of the specification, and the suffix itself does not give any special meaning or function. In describing an embodiment disclosed herein, moreover, the detailed description will be omitted when specific description for publicly known technologies to which the invention pertains is judged to obscure the gist of the present disclosure. Also, it should be noted that the accompanying drawings are merely illustrated to easily explain the concept of the invention, and therefore, they should not be construed to limit the technological concept disclosed herein by the accompanying drawings.

Furthermore, it will be understood that when an element such as a layer, region or substrate is referred to as being “on” another element, it can be directly on the another element or an intermediate element may also be interposed therebetween.

A display device disclosed herein may include a portable phone, a smart phone, a laptop computer, a digital broadcast terminal, a personal digital assistant (PDA), a portable multimedia player (PMP), a navigation, a slate PC, a tablet PC, an ultrabook, a digital TV, a digital signage, a head-mounted display (HMD), a desktop computer, and the like. However, it would be easily understood by those skilled in the art that a configuration disclosed herein may be applicable to any displayable device even though it is a new product type which will be developed later.

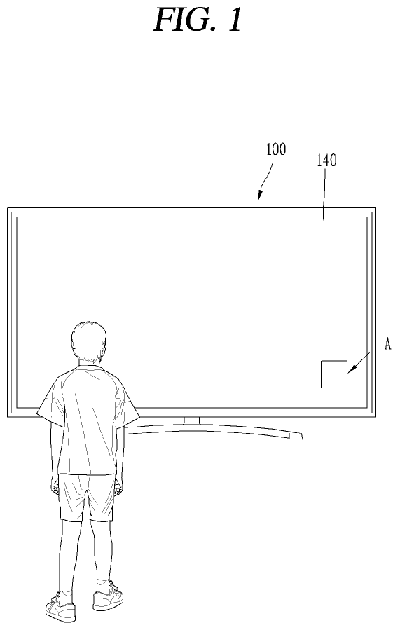

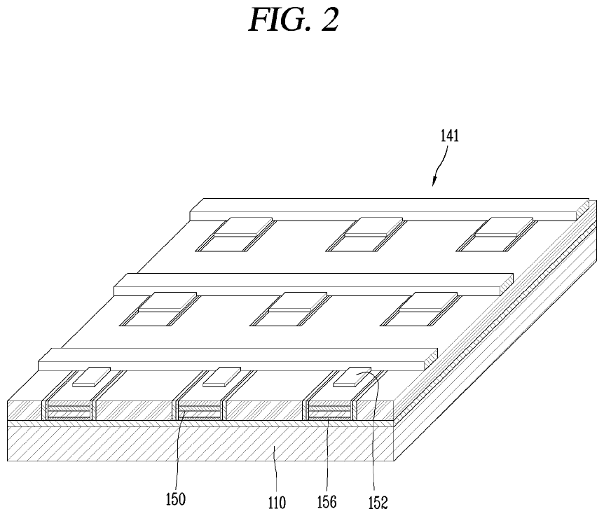

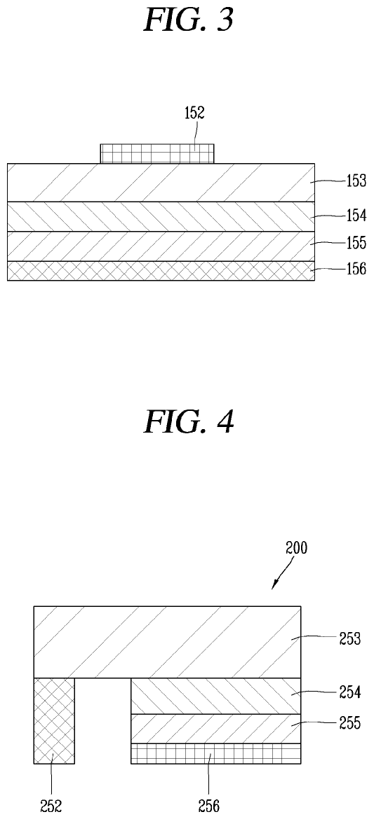

FIG. 1 is a conceptual view showing a display device using a semiconductor light-emitting element according to an embodiment of the present disclosure, and FIG. 2 is a partially enlarged view showing a portion “A” of the display device in FIG. 1, and FIG. 3 is an enlarged view showing a semiconductor light-emitting element in FIG. 2, and FIG. 4 is an enlarged view showing another embodiment of the semiconductor light-emitting element in FIG. 2.

According to the illustration, information processed in the controller of the display device 100 may be displayed on a display module 140. A case 101 in the form of a closed loop surrounding an edge of the display module may form a bezel of the display device.

The display module 140 may include a panel 141 on which an image is displayed, and the panel 141 may include micro-sized semiconductor light-emitting elements 150 and a wiring substrate 110 on which the semiconductor light-emitting elements 150 are mounted.

Wiring lines may be formed on the wiring substrate 110, and connected to an n-type electrode 152 and a p-type electrode 156 of the semiconductor light-emitting element 150. Through this, the semiconductor light-emitting element 150 may be provided on the wiring substrate 110 as a self-emitting individual pixel.

An image displayed on the panel 141 is visual information, and implemented by independently controlling the light emission of a sub-pixel arranged in a matrix form through the wiring lines.

According to the present disclosure, a micro-LED (Light-emitting Diode) is illustrated as one type of the semiconductor light-emitting element 150 that converts current into light. The micro-LED may be a light-emitting diode formed with a small size of 100 microns or less. The semiconductor light-emitting element 150 may be provided in blue, red, and green light-emitting regions, respectively, to implement a sub-pixel by a combination of the light-emitting regions. In other words, the sub-pixel denotes a minimum unit for implementing a single color, and at least three micro-LEDs may be provided in the sub-pixel.

More specifically, referring to FIG. 3, the semiconductor light-emitting element 150 may be a vertical structure.

For example, the semiconductor light-emitting elements 150 may be implemented with a high-power light-emitting element that emits various lights including blue in which gallium nitride (GaN) is mostly used, and indium (In) and or aluminum (Al) are added thereto.

The vertical semiconductor light-emitting element may include a p-type electrode 156, a p-type semiconductor layer 155 formed with the p-type electrode 156, an active layer 154 formed on the p-type semiconductor layer 155, an n-type semiconductor layer 153 formed on the active layer 154, and an n-type electrode 152 formed on the n-type semiconductor layer 153. In this case, the p-type electrode 156 located at the bottom may be electrically connected to a p-electrode of the wiring substrate, and the n-type electrode 152 located at the top may be electrically connected to an n-electrode at an upper side of the semiconductor light-emitting element. The electrodes may be disposed in a top-down direction in the vertical semiconductor light-emitting element 150, thereby providing a great advantage capable of reducing a chip size.

For another example, referring to FIG. 4, the semiconductor light-emitting element may be a flip chip type semiconductor light-emitting element.

For such an example, the semiconductor light-emitting element 250 may include a p-type electrode 256, a p-type semiconductor layer 255 formed with the p-type electrode 256, an active layer 254 formed on the p-type semiconductor layer 255, an n-type semiconductor layer 253 formed on the active layer 254, and an n-type electrode 252 disposed to be separated from the p-type electrode 256 in the horizontal direction on the n-type semiconductor layer 253. In this case, both the p-type electrode 256 and the n-type electrode 252 may be electrically connected to the p-electrode and the n-electrode of the wiring substrate at the bottom of the semiconductor light-emitting element.

The vertical semiconductor light-emitting element and the horizontal semiconductor light-emitting element may be a green semiconductor light-emitting element, a blue semiconductor light-emitting element, or a red semiconductor light-emitting element, respectively. The green semiconductor light-emitting element and the blue semiconductor light-emitting element may be mostly formed of gallium nitride (GaN), and indium (In) and/or aluminum (Al) may be added thereto to implement a high-power light-emitting element that emits green or blue light. For such an example, the semiconductor light-emitting element may be a gallium nitride thin-film formed in various layers such as n-Gan, p-Gan, AlGaN, and InGa, and specifically, the p-type semiconductor layer may be p-type GaN, and the n-type semiconductor layer may be N-type GaN. However, in case of the red semiconductor light-emitting element, the p-type semiconductor layer may be p-type GaAs and the n-type semiconductor layer may be n-type GaAs.

In addition, a p-electrode side in the p-type semiconductor layer may be p-type GaN doped with Mg, and an n-electrode side in the n-type semiconductor layer may be n-type GaN doped with Si. In this case, the above-described semiconductor light-emitting elements may be semiconductor light-emitting elements without an active layer.

On the other hand, referring to FIGS. 1 through 4, since the light-emitting diode is very small, the display panel may be arranged with self-emitting sub-pixels arranged at fine pitch, thereby implementing a high-quality display device.

In a display device using the semiconductor light-emitting element of the present disclosure described above, a semiconductor light-emitting element grown on a wafer and formed through mesa and isolation is used as an individual pixel. In this case, the micro-sized semiconductor light-emitting element 150 must be transferred to a wafer at a predetermined position on the substrate of the display panel. Pick and place is used for the transfer technology, but the success rate is low and a lot of time is required. For another example, there is a technology of transferring a plurality of devices at one time using a stamp or a roll, but the yield is limited and not suitable for a large screen display. The present disclosure proposes a new fabrication method of a display device capable of solving the foregoing problems and a fabrication device using the same.

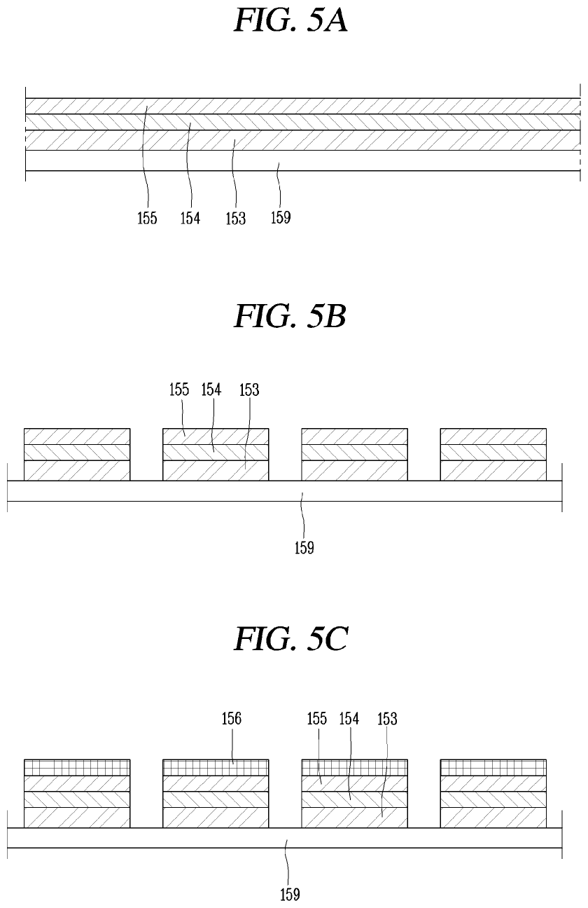

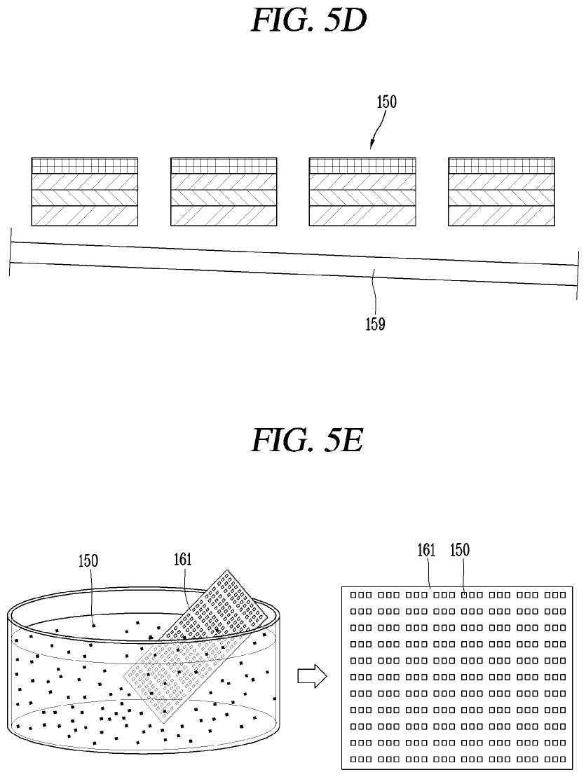

For this purpose, first, a new fabrication method of the display device will be described. FIGS. 5A to 5E are conceptual views for explaining a new process of manufacturing the foregoing semiconductor light-emitting element.

In this specification, a display device using a passive matrix (PM) semiconductor light-emitting element is illustrated. However, an example described below may also be applicable to an active-matrix (AM) type semiconductor light-emitting element. In addition, a method of self-assembling a horizontal semiconductor light-emitting element is illustrated, but it is also applicable to a method of self-assembling a vertical semiconductor light-emitting element.

First, according to a manufacturing method, a first conductive semiconductor layer 153, an active layer 154, and a second conductive semiconductor layer 155 are respectively grown on a growth substrate 159 (FIG. 5A).

When the first conductive semiconductor layer 153 is grown, next, the active layer 154 is grown on the first conductive semiconductor layer 153, and then the second conductive semiconductor layer 155 is grown on the active layer 154. As described above, when the first conductive semiconductor layer 153, the active layer 154 and the second conductive semiconductor layer 155 are sequentially grown, the first conductive semiconductor layer 153, the active layer 154, and the second conductive semiconductor layer 155 form a layer structure as illustrated in FIG. 5A.

In this case, the first conductive semiconductor layer 153 may be a p-type semiconductor layer, and the second conductive semiconductor layer 155 may be an n-type semiconductor layer. However, the present disclosure is not limited thereto, and the first conductive type may be n-type and the second conductive type may be p-type.

In addition, the present embodiment illustrates a case where the active layer is present, but it is also possible to adopt a structure in which the active layer is not present as described above. For such an example, the p-type semiconductor layer may be p-type GaN doped with Mg, and an n-electrode side in the n-type semiconductor layer may be n-type GaN doped with Si.

The growth substrate 159 (wafer) may be formed of any one of materials having light transmission properties, for example, sapphire (Al₂O₃), GaN, ZnO, and AlO, but is not limited thereto. Furthermore, the growth substrate 159 may be formed of a carrier wafer, which is a material suitable for semiconductor material growth. The growth substrate (W) may be formed of a material having an excellent thermal conductivity, and for example, a SiC substrate having a higher thermal conductivity than a sapphire (Al₂O₃) substrate or a SiC substrate including at least one of Si, GaAs, GaP, InP and Ga₂O₃ may be used.

Next, at least part of the first conductive semiconductor layer 153, the active layer 154, and the second conductive semiconductor layer 155 is removed to form a plurality of semiconductor light-emitting elements (FIG. 5B).

More specifically, isolation is performed to allow a plurality of light-emitting elements to form a light-emitting element array. In other words, the first conductive semiconductor layer 153, the active layer 154, and the second conductive semiconductor layer 155 are etched in a vertical direction to form a plurality of semiconductor light-emitting elements.

If it is a case of forming the horizontal semiconductor light-emitting element, then the active layer 154 and the second conductive semiconductor layer 155 may be partially removed in a vertical direction to perform a mesa process in which the first conductive semiconductor layer 153 is exposed to the outside, and then isolation in which the first conductive semiconductor layer is etched to form a plurality of semiconductor light-emitting element arrays.

Next, a second conductive electrode 156 (or a p-type electrode) is respectively formed on one surface of the second conductive semiconductor layer 155 (FIG. 5C). The second conductive electrode 156 may be formed by a deposition process such as sputtering, but the present disclosure is not necessarily limited thereto. However, when the first conductive semiconductor layer and the second conductive semiconductor layer are an n-type semiconductor layer and a p-type semiconductor layer, respectively, the second conductive electrode 156 may also be an n-type electrode.

Then, the growth substrate 159 is removed to provide a plurality of semiconductor light-emitting elements. For example, the growth substrate 159 may be removed using a laser lift-off (LLO) or chemical lift-off (CLO) method (FIG. 5D).

Then, the process of mounting the semiconductor light-emitting elements 150 on the substrate in a chamber filled with a fluid is carried out (FIG. 5E).

For example, the semiconductor light-emitting elements 150 and the substrate are placed in a chamber filled with a fluid, and the semiconductor light-emitting elements are assembled to the substrate 161 by themselves using flow, gravity, surface tension, or the like. In this case, the substrate may be an assembly substrate 161.

For another example, the wiring substrate may also be placed in the fluid chamber instead of the assembly substrate 161 such that the semiconductor light-emitting elements 150 are directly seated on the wiring substrate. In this case, the substrate can be a wiring substrate. However, for convenience of description, in the present disclosure, it is illustrated that the substrate is provided as an assembly substrate 161 and the semiconductor light-emitting elements 1050 are seated thereon.

Cells (not shown) into which the semiconductor light-emitting elements 150 are fitted may be provided on the assembly substrate 161 so that the semiconductor light-emitting elements 150 are easily seated on the assembly substrate 161. Specifically, cells on which the semiconductor light-emitting elements 150 are seated are formed on the assembly substrate 161 at a position where the semiconductor light-emitting elements 150 are aligned with the wiring electrode. The semiconductor light-emitting elements 150 are assembled into the cells while moving in the fluid.

When the plurality of semiconductor light-emitting elements are arrayed on the assembly substrate 161, and then the semiconductor light-emitting elements on the assembly substrate 161 are transferred to the wiring substrate, it may enable large-area transfer. Therefore, the assembly substrate 161 may be referred to as a temporary substrate.

Meanwhile, the self-assembly method described above must increase transfer yield when applied to the fabrication of a large-screen display. The present disclosure proposes a method and apparatus for minimizing the influence of gravity or friction and preventing non-specific binding in order to increase the transfer yield.

In this case, in a display device according to the present disclosure, a magnetic body is disposed on the semiconductor light-emitting element to move the semiconductor light-emitting element using a magnetic force, and place the semiconductor light-emitting element at preset position using an electric field in the movement process. Hereinafter, such a transfer method and device will be described in more detail with reference to the accompanying drawings.

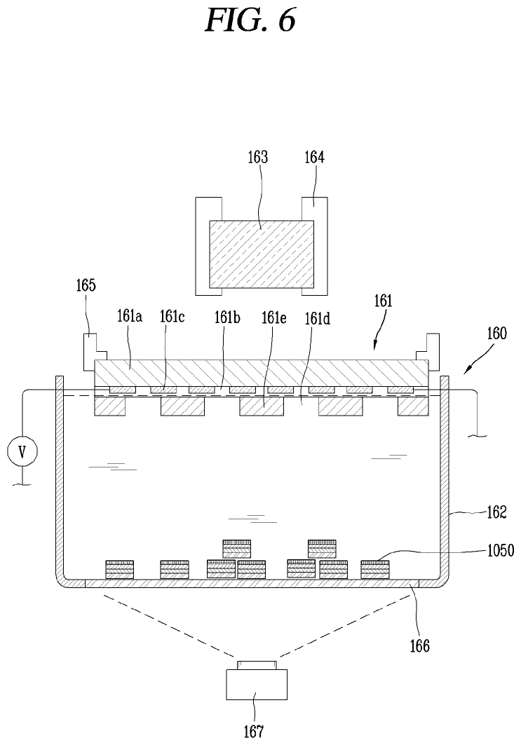

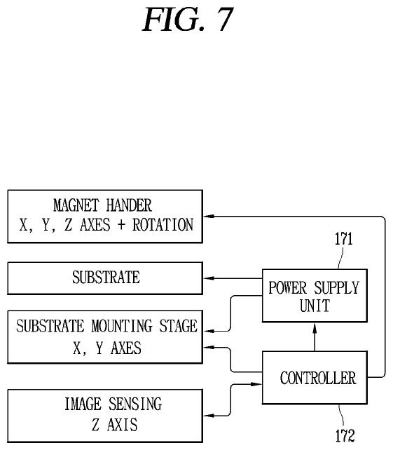

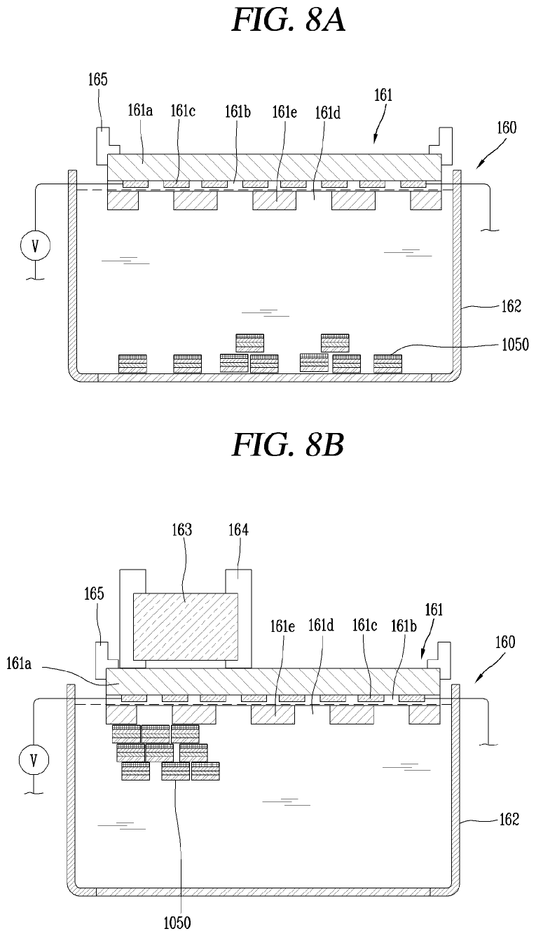

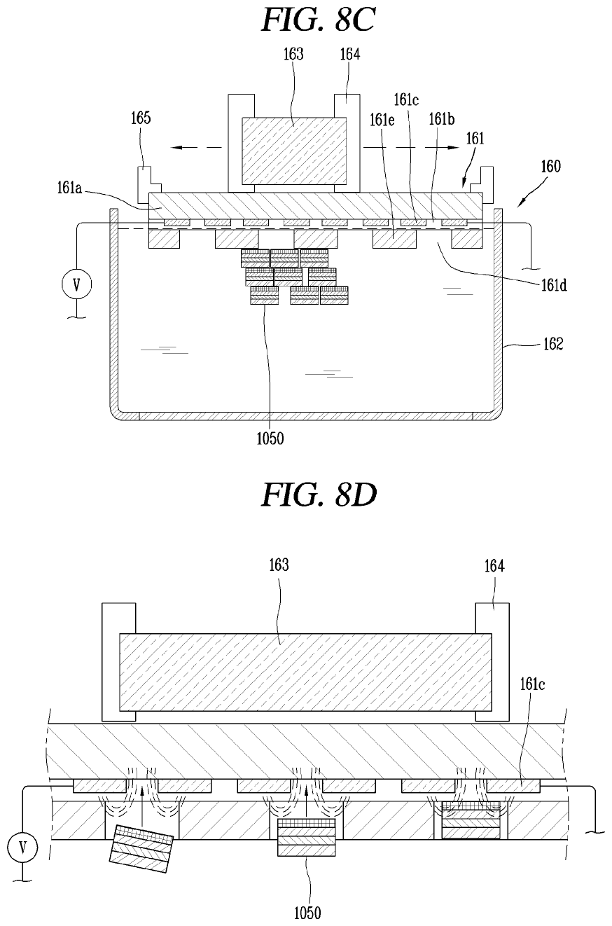

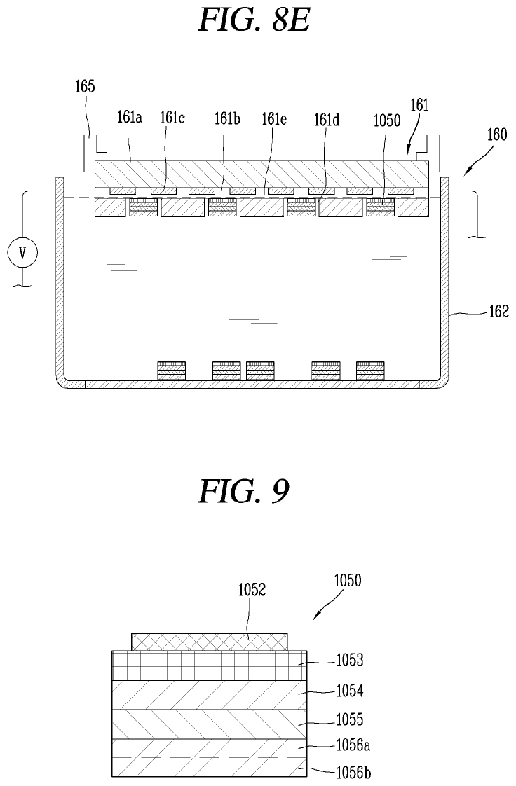

FIG. 6 is a conceptual view showing an example of a self-assembly device of semiconductor light-emitting elements according to the present disclosure, and FIG. 7 is a block diagram showing the self-assembly device in FIG. 6. FIGS. 8A to 8E are conceptual views showing a process of self-assembling semiconductor light-emitting elements using the self-assembly device in FIG. 6, and FIG. 9 is a conceptual view for explaining the semiconductor light-emitting element in FIGS. 8A to 8E.

According to the illustration of FIGS. 6 and 7, a self-assembly device 160 of the present disclosure may include a fluid chamber 162, a magnet 163, and a location controller 164.

The fluid chamber 162 has a space for accommodating a plurality of semiconductor light-emitting elements. The space may be filled with a fluid, and the fluid may include water or the like as an assembly solution. Accordingly, the fluid chamber 162 may be a water tank, and may be configured with an open type. However, the present disclosure is not limited thereto, and the fluid chamber 162 may be a closed type in which the space is formed with a closed space.

The substrate 161 may be disposed on the fluid chamber 162 such that an assembly surface on which the semiconductor light-emitting elements 150 are assembled faces downward. For example, the substrate 161 may be transferred to an assembly position by a transfer unit, and the transfer unit may include a stage 165 on which the substrate is mounted. The stage 165 is positioned by the controller, and the substrate 161 may be transferred to the assembly position through the stage 165.

At this time, the assembly surface of the substrate 161 faces the bottom of the fluid chamber 150 at the assembly position. According to the illustration, the assembly surface of the substrate 161 is disposed so as to be immersed in a fluid in the fluid chamber 162. Therefore, the semiconductor light-emitting elements 150 are moved to the assembly surface in the fluid.

The substrate 161, which is an assembly substrate on which an electric field can be formed, may include a base portion 161a, a dielectric layer 161b and a plurality of electrodes 161c.

The base portion 161a may be made of an insulating material, and the plurality of electrodes 161c may be a thin or a thick film bi-planar electrode patterned on one side of the base portion 161a. The electrode 161c may be formed of, for example, a laminate of Ti/Cu/Ti, an Ag paste, ITO, and the like.

The dielectric layer 161b is made of an inorganic material such as SiO₂, SiNx, SiON, Al₂₃, TiO₂, HfO₂, or the like. Alternatively, the dielectric layer 161b may be composed of a single layer or multiple layers as an organic insulator. A thickness of the dielectric layer 161b may be several tens of nanometers to several micrometers.

Furthermore, the substrate 161 according to the present disclosure includes a plurality of cells 161d partitioned by partition walls. The cells 161d may be sequentially arranged along one direction, and made of a polymer material. In addition, the partition wall 161e constituting the cells 161d is configured to be shared with neighboring cells 161d. The partition walls 161e are protruded from the base portion 161a, and the cells 161d may be sequentially arranged along the one direction by the partition walls 161e. More specifically, the cells 161d are sequentially arranged in row and column directions, and may have a matrix structure.

As shown in the drawing, an inside of the cells 161d has a groove for accommodating the semiconductor light-emitting element 150, and the groove may be a space defined by the partition walls 161e. The shape of the groove may be the same as or similar to that of the semiconductor light-emitting element. For example, when the semiconductor light-emitting element is in a rectangular shape, the groove may be a rectangular shape. In addition, although not shown, when the semiconductor light-emitting element is circular, the grooves formed in the cells may be formed in a circular shape. Moreover, each of the cells is configured to accommodate a single semiconductor light-emitting element. In other words, a single semiconductor light-emitting element is accommodated in a single cell.

Meanwhile, the plurality of electrodes 161c include a plurality of electrode lines disposed at the bottom of each of the cells 161d, and the plurality of electrode lines may be configured to extend to neighboring cells.

The plurality of electrodes 161c are disposed below the cells 161d and applied with different polarities to generate an electric field in the cells 161d. In order to form the electric field, the dielectric layer may form the bottom of the cells 161d while the dielectric layer covers the plurality of electrodes 161c. In such a structure, when different polarities are applied to a pair of electrodes 161c from a lower side of each cell 161d, an electric field may be formed, and the semiconductor light-emitting element may be inserted into the cells 161d by the electric field.

At the assembly position, the electrodes of the substrate 161 are electrically connected to the power supply unit 171. The power supply unit 171 applies power to the plurality of electrodes to generate the electric field.

According to the illustration, the self-assembly device may include a magnet 163 for applying a magnetic force to the semiconductor light-emitting elements. The magnet 163 is spaced apart from the fluid chamber 162 to apply a magnetic force to the semiconductor light-emitting elements 150. The magnet 163 may be disposed to face an opposite side of the assembly surface of the substrate 161, and the location of the magnet is controlled by the location controller 164 connected to the magnet 163.

The semiconductor light-emitting element 1050 may have a magnetic body so as to move in the fluid by the magnetic field of the magnet 163.

Referring to FIG. 9, the semiconductor light-emitting element of the display device having a magnetic body may include a first conductive electrode 1052 and a second conductive electrode 1056, a first conductive semiconductor layer 1053 disposed with the first conductive electrode 1052, a second conductive semiconductor layer 1055 configured to overlap with the first conductive semiconductor layer 1052, and disposed with the second conductive electrode 1056, and an active layer 1054 disposed between the first and second conductive semiconductor layers 1053, 1055.

Here, the first conductive type and the second conductive type may be composed of p-type and n-type, and vice versa. In addition, as described above, it may be a semiconductor light-emitting element without having the active layer.

Meanwhile, in the present disclosure, the first conductive electrode 1052 may be generated after the semiconductor light-emitting element is assembled to the wiring board by the self-assembly of the semiconductor light-emitting element. In addition, in the present disclosure, the second conductive electrode 1056 may include the magnetic body. The magnetic body may refer to a metal having magnetism. The magnetic body may be Ni, SmCo or the like, and for another example, a material corresponding to at least one of Gd-based, La-based, and Mn-based materials.

The magnetic body may be provided in the second conductive electrode 1056 in the form of particles. Furthermore, alternatively, for a conductive electrode including a magnetic body, a single layer of the conductive electrode may be made of a magnetic body. For such an example, as illustrated in FIG. 9, the second conductive electrode 1056 of the semiconductor light-emitting element 1050 may include a first layer 1056a and a second layer 1056b. Here, the first layer 1056a may be made to include a magnetic material, and the second layer 1056b may include a metal material other than the magnetic material.

As illustrated, in this example, the first layer 1056a including a magnetic body may be disposed to be in contact with the second conductive semiconductor layer 1055. In this case, the first layer 1056a is disposed between the second layer 1056b and the second conductive semiconductor layer 1055. The second layer 1056b may be a contact metal connected to the second electrode of the wiring substrate. However, the present disclosure is not necessarily limited thereto, and the magnetic body may be disposed on one surface of the first conductive semiconductor layer.

Referring again to FIGS. 6 and 7, more specifically, the self-assembly device may include a magnet handler that can be automatically or manually moved in the x, y, and z axes on the top of the fluid chamber or include a motor capable of rotating the magnet 163. The magnet handler and the motor may constitute the location controller 164. Through this, the magnet 163 rotates in a horizontal direction, a clockwise direction, or a counterclockwise direction with respect to the substrate 161.

On the other hand, a light transmitting bottom plate 166 may be formed in the fluid chamber 162, and the semiconductor light-emitting elements may be disposed between the bottom plate 166 and the substrate 161. An image sensor 167 may be positioned to view the bottom plate 166 so as to monitor an inside of the fluid chamber 162 through the bottom plate 166. The image sensor 167 is controlled by the controller 172, and may include an inverted type lens, a CCD, and the like to observe the assembly surface of the substrate 161.

The self-assembling apparatus described above is configured to use a combination of a magnetic field and an electric field, and using those fields, the semiconductor light-emitting elements may be placed at preset positions of the substrate by an electric field in the process of being moved by a location change of the magnet. Hereinafter, an assembly process using the self-assembly device described above will be described in more detail.

First, a plurality of semiconductor light-emitting elements 1050 having magnetic bodies are formed through the process described with reference to FIGS. 5A to 5C. In this case, a magnetic body may be deposited on the semiconductor light-emitting element in the process of forming the second conductive electrode in FIG. 5C.

Next, the substrate 161 is transferred to the assembly position, and the semiconductor light-emitting elements 1050 are placed into the fluid chamber 162 (FIG. 8A).

As described above, the assembly position of the substrate 161 is a position at which the assembly surface on which the semiconductor light-emitting elements 1050 of the substrate 161 are assembled is disposed in a downward direction in the fluid chamber 162.

In this case, some of the semiconductor light-emitting elements 1050 may sink to the bottom of the fluid chamber 162 and some may float in the fluid. The light transmitting bottom plate 166 may be provided in the fluid chamber 162, and some of the semiconductor light-emitting elements 1050 may sink to the bottom plate 166.

Next, a magnetic force is applied to the semiconductor light-emitting elements 1050 so that the semiconductor light-emitting elements 1050 float in the fluid chamber 162 in a vertical direction (FIG. 8B).

When the magnet 163 of the self-assembly device moves from its original position to an opposite side of the assembly surface of the substrate 161, the semiconductor light-emitting elements 1050 float in the fluid toward the substrate 161. The original position may be a position away from the fluid chamber 162. For another example, the magnet 163 may be composed of an electromagnet. In this case, electricity is supplied to the electromagnet to generate an initial magnetic force.

Meanwhile, in this example, a separation distance between the assembly surface of the substrate 161 and the semiconductor light-emitting elements 1050 may be controlled by adjusting the magnitude of the magnetic force. For example, the separation distance is controlled using the weight, buoyancy, and magnetic force of the semiconductor light-emitting elements 1050. The separation distance may be several millimeters to tens of micrometers from the outermost edge of the substrate.

Next, a magnetic force is applied to the semiconductor light-emitting elements 1050 so that the semiconductor light-emitting elements 1050 move in one direction in the fluid chamber 162. For example, the magnet 163 moves in a horizontal direction, a clockwise direction or a counterclockwise direction with respect to the substrate (FIG. 8C). In this case, the semiconductor light-emitting elements 1050 move in a direction parallel to the substrate 161 at a position spaced apart from the substrate 161 by the magnetic force.

Next, the process of applying an electric field to guide the semiconductor light-emitting elements 1050 to preset positions of the substrate 161 so as to allow the semiconductor light-emitting elements 1050 to be placed at the preset positions during the movement of the semiconductor light-emitting elements 250 is carried out (FIG. 8C). For example, the semiconductor light-emitting elements 1050 move in a direction perpendicular to the substrate 161 by the electric field to be placed at preset positions of the substrate 161 while moving along a direction parallel to the substrate 161.

More specifically, electric power is supplied to a bi-planar electrode of the substrate 161 to generate an electric field to carry out assembly only at preset positions. In other words, the semiconductor light-emitting elements 1050 are assembled to the assembly position of the substrate 161 using a selectively generated electric field. For this purpose, the substrate 161 may include cells in which the semiconductor light-emitting elements 1050 are inserted.

Then, the unloading process of the substrate 161 is carried out, and the assembly process is completed. When the substrate 161 is an assembly substrate, a post-process of transferring the aligned semiconductor light-emitting elements to a wiring substrate as described above to implement a display device may be carried out.

On the other hand, the semiconductor light-emitting elements 1050 may be guided to the preset positions, then the magnet 163 may move in a direction away from the substrate 161 such that the semiconductor light-emitting elements 1050 remaining in the fluid chambers 162 fall to the bottom of the fluid chambers 162, (FIG. 8D). For another example, if power supply is stopped when the magnet 163 is an electromagnet, then the semiconductor light-emitting elements 1050 remaining in the fluid chamber 162 fall to the bottom of the fluid chamber 162.

Then, when the semiconductor light-emitting elements 1050 on the bottom of the fluid chamber 162 are collected, the collected semiconductor light-emitting elements 1050 may be reused.

The above-described self-assembly device and method are characterized in that, in order to increase the assembly yield in a fluidic assembly, parts at a far distance are concentrated adjacent to a preset assembly site using a magnetic field, and a separate electric field is applied to the assembly site to selectively assemble the parts only in the assembly site. At this time, the assembly substrate is placed on an upper portion of the water tank and the assembly surface faces downward, thereby preventing nonspecific coupling while minimizing the effect of gravity due to the weight of parts. In other words, in order to increase the transfer yield, the assembly substrate is placed on the top to minimize the effect of a gravitational or frictional force, and prevent nonspecific coupling.

As described above, according to the present disclosure having the foregoing configuration, a large number of semiconductor light-emitting elements may be assembled at one time in a display device in which individual pixels are formed with semiconductor light-emitting elements.

Meanwhile, in order to improve the picture quality of a display device, the number of pixels included in a display must be increased. In order to increase the number of pixels of the display device, a size of a semiconductor light-emitting element must be reduced. As the size of the semiconductor light-emitting element decreases, a yield according to the above-described self-assembly method may decrease.

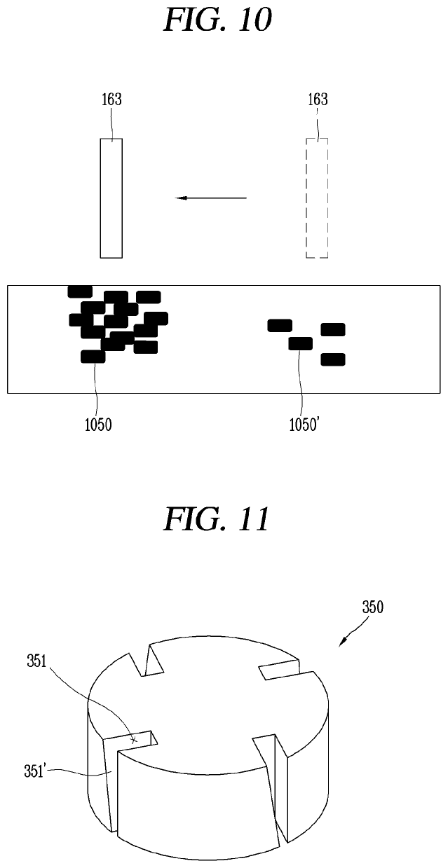

FIG. 10 is a conceptual view showing a semiconductor light-emitting element that sinks to a bottom of a fluid chamber during self-assembly.

Specifically, when the size of the semiconductor light-emitting element decreases, an amount of a magnetic material included in the semiconductor light-emitting element decreases, and thus a strength of a magnetic force acting on the semiconductor light-emitting element decreases. A magnetic force, an electric force, and a gravitational force act on the semiconductor light-emitting element dispersed in the fluid during self-assembly. As a size of the semiconductor light-emitting element decreases, the effect of gravity acting on the semiconductor light-emitting element increases. Accordingly, referring to FIG. 10, there may be a semiconductor light-emitting element 1050′ that sinks to the bottom of the fluid chamber without following the magnet during self-assembly. In the present specification, such a phenomenon is referred to as tailing. As the number of semiconductor light-emitting elements 1050′ on which the above-described tailing occurs increases, the number of semiconductor light-emitting elements participating in self-assembly decreases, and the self-assembly yield also decreases.

The present disclosure provides a structure and method capable of maintaining a high self-assembly yield even when the size of a semiconductor light-emitting element decreases. Specifically, the present disclosure provides a structure and method capable of minimizing the above-described tailing even when the size of the semiconductor light-emitting element is reduced.

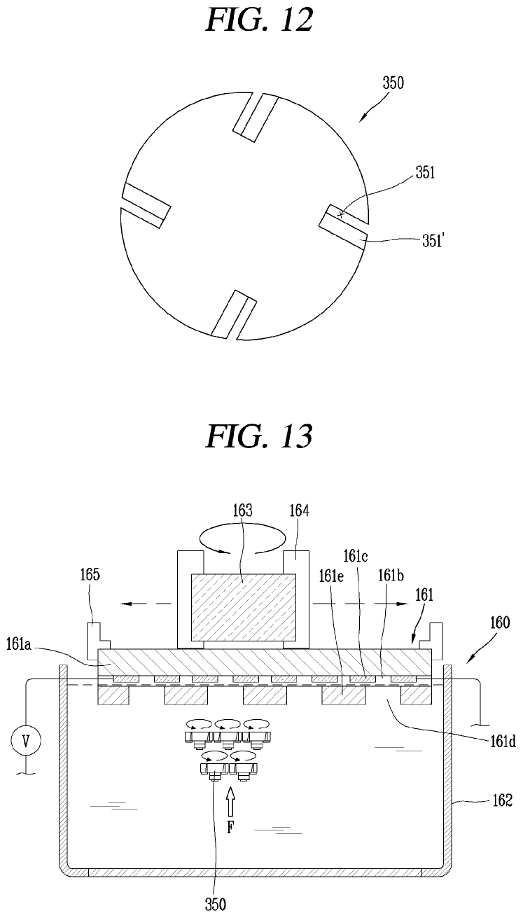

FIG. 11 is a perspective view showing a semiconductor light-emitting element according to an embodiment of the present disclosure, and FIG. 12 is a plan view showing a semiconductor light-emitting element according to an embodiment of the present disclosure.

Each of the semiconductor light-emitting elements included in a display device according to the present disclosure includes a plurality of recessed portions formed on a side surface thereof, and at least one of inner walls of each of the recessed portions is formed to be inclined with respect to one surface of the semiconductor light-emitting element in contact with the substrate.

Referring to FIGS. 11 and 12, a plurality of recessed portions 351 are formed on a side surface of the semiconductor light-emitting element. As shown in FIG. 11, the recessed portion 351 may be formed to pass through a portion of the semiconductor light-emitting element 350 in a thickness direction of the semiconductor light-emitting element. In this case, recessed portions exist on all end surfaces of the semiconductor light-emitting element cut with a plane parallel to an upper surface or a lower surface of the semiconductor light-emitting element.

However, the present disclosure is not limited thereto, and the recessed portion may be formed only on a portion of a side surface of the semiconductor light-emitting element. In this case, the recessed portion does not exist on a portion of the cross-sections of the semiconductor light-emitting element cut with a plane parallel to the upper surface or the lower surface of the semiconductor light-emitting element. Such a structure will be described later.

Meanwhile, there exists an inner wall in each recessed portion. As shown in FIG. 11, each of the recessed portions 351 may have three inner walls. However, the number of inner walls provided in the recessed portion is not limited to three. The recessed portion may include the two inner walls or four or more inner walls.

At least one of the plurality of inner walls is formed to be inclined with respect to one surface of the semiconductor light-emitting element in contact with the substrate. In an embodiment, referring to FIG. 11, any one 351′ of two inner walls facing each other among inner walls provided in the recessed portion may be formed to be inclined with respect to a lower surface of the semiconductor light-emitting element.

The above-described recessed portion serves to minimize tailing during self-assembly described with reference to FIGS. 8A to 8E.

FIG. 13 is a conceptual view showing a self-assembly method using a semiconductor light-emitting element according to the present disclosure.

Referring to FIG. 13, during self-assembly, the semiconductor light-emitting element according to the present disclosure is assembled on a substrate with the upper surface thereof facing a bottom surface of the fluid chamber. For example, during self-assembly, a surface shown in FIG. 12 is assembled onto the substrate while facing the fluid chamber.

During self-assembly, when the magnet 163 is rotated and moved in one direction at the same time, the semiconductor light-emitting element moves in one direction while rotating along the magnet 163. As the semiconductor light-emitting element rotates, a lift force F acts on an inclined surface provided in the recessed portion.

When the semiconductor light-emitting element rotates with the upper surface of the semiconductor light-emitting element facing the bottom surface of the fluid chamber, a lift force F in a direction toward the substrate is applied to the semiconductor light-emitting element. Accordingly, a magnetic force, an electric force, a lift force, and a gravitational force act together on the semiconductor light-emitting element. Since the lift force F acts in a direction opposite to gravity, it compensates for the reduced magnetic force as the size of the semiconductor light-emitting element becomes smaller.

Due to the lift force F, the semiconductor light-emitting elements always stay in a position close to the substrate. For this reason, when the magnet moves along one direction, the number of semiconductor light-emitting elements sinking away from the magnet to the bottom surface of the fluid chamber is reduced. That is, the recessed portion allows a lift force in a direction opposite to gravity to act on the semiconductor light-emitting element, thereby minimizing tailing.

Meanwhile, the above-described recessed portion may be applied in various forms. Hereinafter, a modified embodiment of the above-described recessed portion will be described.

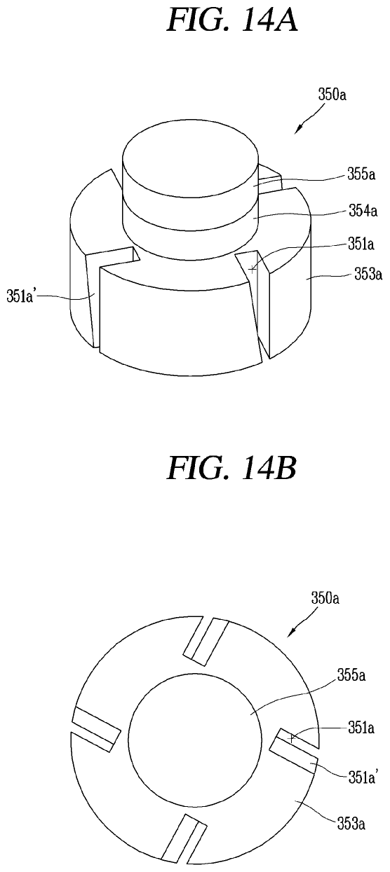

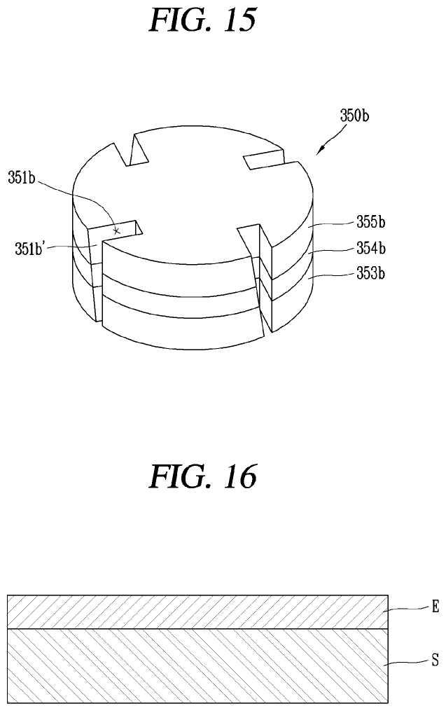

FIG. 14A is a perspective view showing a flip-chip type semiconductor light-emitting element having a recessed portion, FIG. 14B is a plan view showing a flip-chip type semiconductor light-emitting element having a recessed portion, and FIG. 15 is a perspective view showing a horizontal type semiconductor light-emitting element having a recessed portion.

Referring to FIGS. 14A and 14B, the recessed portion may be applied to a flip-chip type semiconductor light-emitting element.

Specifically, each of the semiconductor light-emitting elements includes first and second conductive electrodes, a first conductive semiconductor layer disposed on the substrate, an active layer deposited on a portion of the first conductive semiconductor layer, and a second conductive semiconductor layer deposited on the active layer, and the first conductive electrode may be disposed on one surface on which the active layer is deposited between both surfaces of the first conductive semiconductor layer.

Here, each of the recessed portions is formed on a side surface of the first conductive semiconductor layer. In an embodiment, referring to FIGS. 14A and 14B, an active layer 354a and a second conductive semiconductor layer 355a are formed on a first conductive semiconductor layer 353a, and the active layer 354a and the second conductive semiconductor layer 355a overlaps a portion of the first conductive semiconductor layer 353a. Accordingly, one surface of the first conductive semiconductor layer 353a in contact with the active layer 354a is exposed to the outside. Although not shown, the first conductive electrode is formed on one surface exposed to the outside.

Meanwhile, the recessed portion 351a is formed on a side surface of the first conductive semiconductor layer 353a. The recessed portion 351a may be formed to pass through the first conductive semiconductor layer 353a in a thickness direction of the first conductive semiconductor layer 353a. When looking at the semiconductor light-emitting element as a whole, the recessed portion 351a is formed on a portion of a side surface of the semiconductor light-emitting element.

Meanwhile, an inner wall of the recessed portion may include at least one inclined surface 351a′. During self-assembly, the inclined surface 351a′ applies a lift force to the semiconductor light-emitting element.

Alternatively, referring to FIG. 15, the recessed portion may be applied to a horizontal type semiconductor light-emitting element.

Each of the semiconductor light-emitting elements includes first and second conductive electrodes, a first conductive semiconductor layer disposed on the substrate, an active layer deposited on a portion of the first conductive semiconductor layer, and a second conductive semiconductor layer deposited on the active layer, and the first conductive electrode is disposed on one surface facing the substrate between both surfaces of the first conductive electrode, and the second conductive electrode is disposed on one surface facing a direction opposite to a direction facing the substrate between both surfaces of the second conductive electrode.

Here, each of the recessed portions are formed on a side surface of each of the first conductive semiconductor layer, the active layer, and the second conductive semiconductor layer. In an embodiment, referring to FIG. 15, an active layer 354b and a second conductive semiconductor layer 355b are sequentially deposited on a first conductive semiconductor layer 353b. Although not shown, the first conductive electrode is disposed on one surface that is not in contact with the active layer between both surfaces of the first conductive semiconductor layer, and the second conductive electrode is disposed on one surface that is not in contact with the active layer between both surfaces of the second conductive semiconductor layer.

Meanwhile, a recessed portion 351b is formed in each of the first conductive semiconductor layer 353b, the active layer 354b, and the second conductive semiconductor layer 355b. When looking at the semiconductor light-emitting element as a whole, the recessed portion 351b is formed to pass through the semiconductor light-emitting element in a thickness direction of the semiconductor light-emitting element.

Meanwhile, the recessed portion may include a plurality of inclined surfaces disposed adjacent to each other. Here, an angle between each of the plurality of inclined surfaces and one surface of the semiconductor light-emitting element in contact with the substrate may increase as a distance from the substrate increases. A method for manufacturing the above-described semiconductor light-emitting element will be described later.

Meanwhile, an area of each of the plurality of inclined surfaces may increase as an angle between each of the plurality of inclined surfaces and one surface of the semiconductor light-emitting element in contact with the substrate becomes smaller. Through this, the present disclosure maximizes a lift force acting on the inclined surface.

As described above, the recessed portion according to the present disclosure may be applied to various types of semiconductor light-emitting elements. According to the present disclosure, a lift force in a direction opposite to gravity acts on the semiconductor light-emitting element during self-assembly. Through this, the present disclosure minimizes tailing occurring when a magnetic force acting on the semiconductor light-emitting element is weakened.

Hereinafter, a method of manufacturing a display device including the above-described semiconductor light-emitting element will be described.

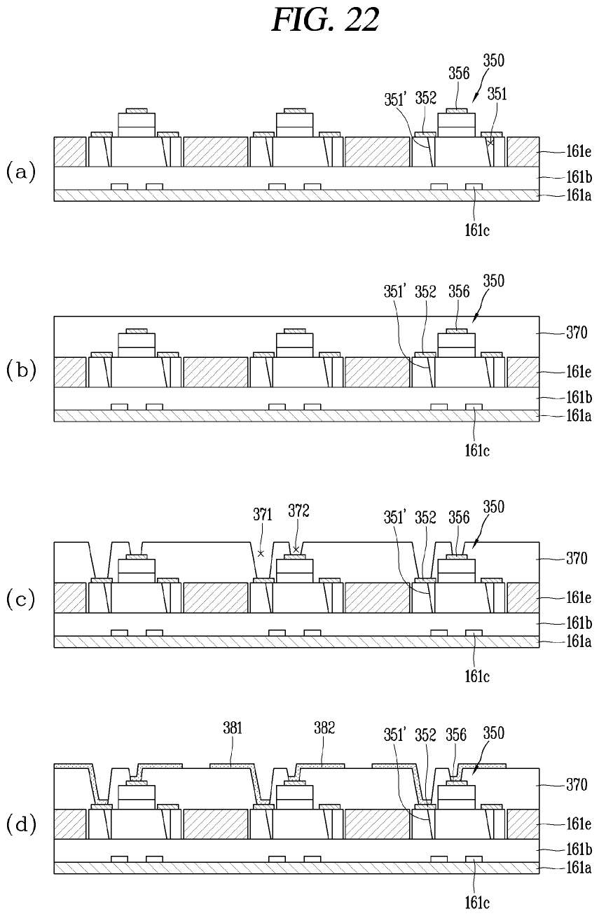

FIGS. 16 to 21 are conceptual views showing a method of manufacturing a semiconductor light-emitting element included in a display device according to the present disclosure, and FIG. 22 is a conceptual view showing a process of forming a wiring electrode after self-assembly.

Hereinafter, with reference to the accompanying drawings, a step of manufacturing the semiconductor light-emitting element having a recessed portion on a side surface thereof will be described in detail.

Referring to FIG. 16, a step of forming an epitaxial layer (E) in which a first conductive semiconductor layer, an active layer, and a second conductive semiconductor layer are sequentially deposited on a growth substrate (S) is performed.

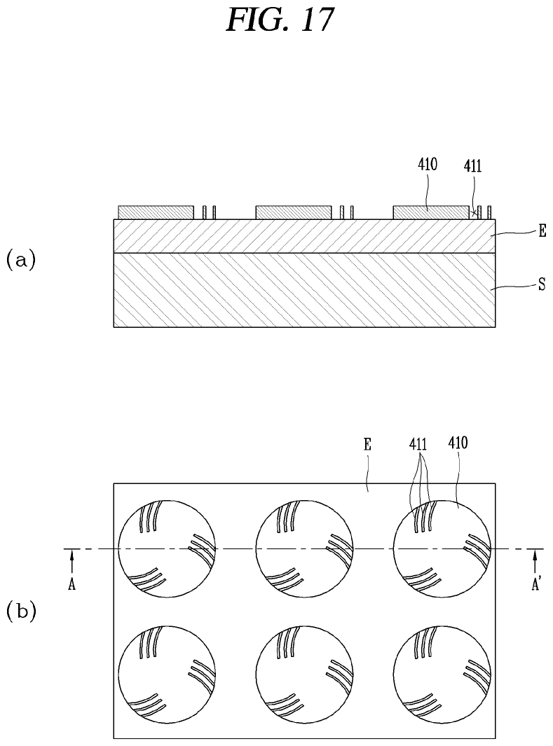

Then, referring to FIG. 17, a step of depositing a photoresist layer 410 in which a plurality of slits 411 are continuously disposed on the second conductive semiconductor layer is performed.

The manufacturing method of the semiconductor light-emitting element described with reference to FIGS. 16 to 19 illustrates a manufacturing method of a horizontal semiconductor light-emitting element. In the case of manufacturing a flip-chip type semiconductor light-emitting element, the above-described step of forming the photoresist layer is performed after a mesa process.

That is, the above-described step of forming the photoresist layer 410 may be performed after a step of etching a portion of layers deposited on the first conductive semiconductor layer so that a portion of the first conductive semiconductor layer is exposed to the outside.

On the other hand, referring to FIG. 17, the photoresist layer 410 may include a plurality of slits 411. The plurality of slits 411 are disposed adjacent to one another, and the slits 411 disposed adjacent to one another allow the recessed portion 420 having an inclined surface to be formed during an isolation process to be described later.

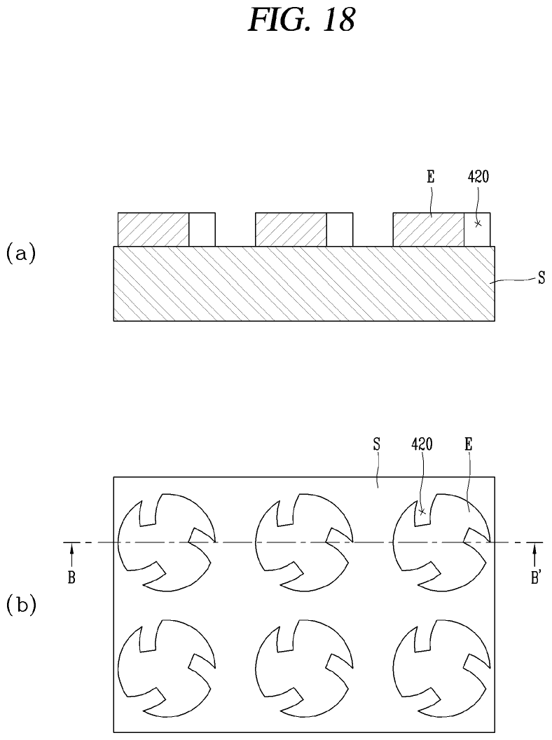

Referring to FIG. 18, a step of irradiating light onto the photoresist layer 410 to form semiconductor light-emitting elements having a plurality of recessed portions 420 on a side surface thereof is performed. Here, a step of irradiating light to the continuously disposed slits to form the recessed portion 420 including an inclined surface is performed together. That is, the isolation process and the process of forming the recessed portion may be simultaneously performed. Then, a step of removing the photoresist layer 410 is performed.

An angle and a shape of the inclined surface may vary according to a shape of the slit provided in the above-described photoresist layer 410.

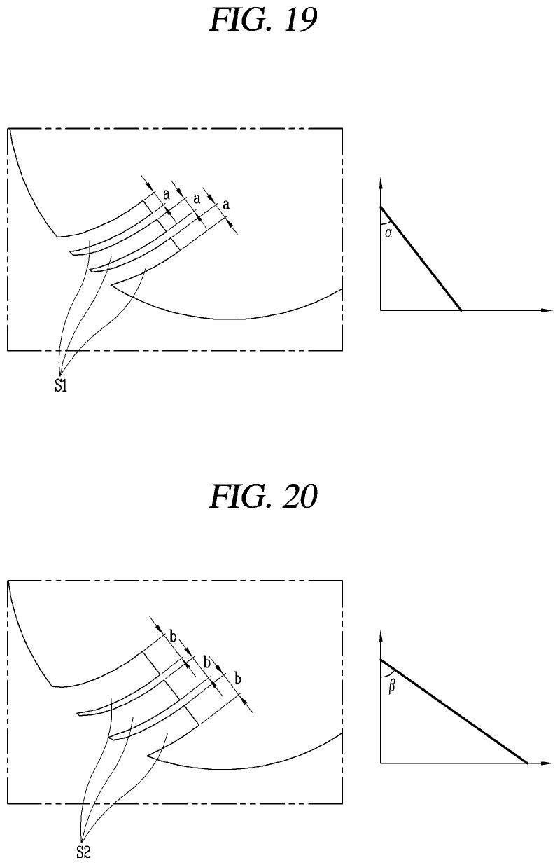

In an embodiment, referring to FIG. 19, widths of slits S1 may be uniformly formed. In this case, an angle of the inclined surface with respect to a sidewall of the semiconductor light-emitting element becomes α.

In another embodiment, referring to FIG. 20, widths of slits S2 may be uniformly formed, and may be formed to have a width larger than that of the slits described with reference to FIG. 19. In this case, the angle of the inclined surface with respect to the sidewall of the semiconductor light-emitting element becomes α larger than α. Describing in other words, an angle between one surface and the inclined surface of the semiconductor light-emitting element in contact with the substrate is greater in the embodiment of FIG. 19 than in the embodiment of FIG. 20.

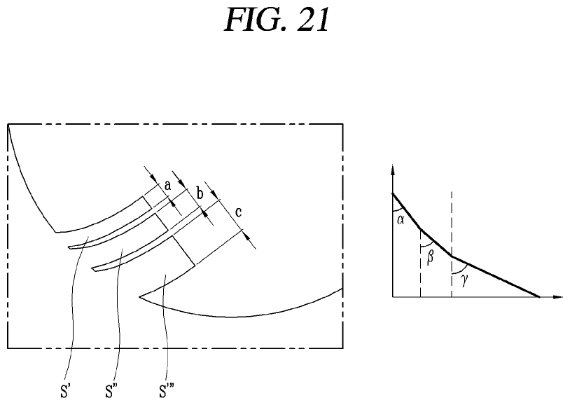

In another embodiment, referring to FIG. 21, the slits S′, S″, and S″′ may be formed to increase in width in one direction. In this case, a plurality of inclined surfaces are formed, and the angle of the inclined surfaces with respect to each of the plurality of inclined surfaces and the sidewall of the light-emitting element decreases as a distance from the substrate increases. Describing in other words, an angle of the one surface of the semiconductor light-emitting element in contact with the substrate and each of the plurality of inclined surfaces increases as the distance from the substrate increases.

Meanwhile, after self-assembly is completed, wiring electrodes may be formed on the semiconductor light-emitting elements. A process described in FIG. 22 is a process applied to a flip-chip type semiconductor light-emitting element.

Referring to FIG. 22, after assembling semiconductor light-emitting elements at preset positions on an assembly substrate by inducing the movement of the semiconductor light-emitting elements in a fluid chamber by the above-described process, a planarization layer 370 is filled between the plurality of semiconductor light-emitting elements ((b) of FIG. 22). More specifically, as described above, a gap exists between a groove 161d formed on the assembly substrate and the semiconductor light-emitting element. The planarization layer 370 fills the gap while covering the semiconductor light-emitting element together with the partition walls. Meanwhile, in a process of forming the above-described planarization layer 370, the recessed portion may be filled with a material constituting the planarization layer.

Through such a process, a structure in which the planarization layer 370 surrounds the semiconductor light-emitting element may be formed on the display. In this case, the planarization layer 370 may be made of a polymer material so as to be integrated with the partition walls. Although FIG. 22 shows the planarization layer 370 and the partition wall 161e separately for convenience of description, in reality, the planarization layer 370 and the partition wall 161e may constitute a single layer. That is, when the planarization layer 370 is formed, the partition wall 161e becomes a portion of the planarization layer 370.

In a display device implemented by the process illustrated in FIG. 22, the planarization layer 370 may include a plurality of cells, and the plurality of semiconductor light-emitting elements 350 may be accommodated in the cells. In other words, the cells that have been provided in the self-assembly process in the final structure are changed into the internal spaces of the planarization layer 370.

Contact holes 371, 372 may be formed for wiring ((c) of FIG. 22). The contact holes 371, 372 may be formed in the first conductive electrode 352 and the second conductive electrode 356, respectively.

Finally, a first wiring electrode 381 and a second wiring electrode 382 are connected to the plurality of semiconductor light-emitting elements through the contact holes ((d) of FIG. 22).

The first wiring electrode 381 and the second wiring electrode 382 may be extended to one surface of the planarization layer 370. At this time, one surface of the planarization layer 370 may be a surface opposite to a surface covering the dielectric layer 261b. For example, the first wiring electrode 381 is extended to an upper surface of the planarization layer 370 on the first conductive electrode 352 through a first contact hole 371 formed on the first conductive electrode 352. The second wiring electrode 382 is extended to an upper surface of the planarization layer 370 through a second contact hole 372 formed on the second conductive electrode 356.

The manufacturing method described with reference to FIG. 22 is limited to a flip-chip type semiconductor light-emitting element. In the case of a horizontal type semiconductor light-emitting element, a portion of a wiring electrode must be formed on a bottom surface of a groove, and the wiring electrode formed on the bottom surface of the groove and the semiconductor light-emitting element are electrically connected during self-assembly or by a self-assembly post-process. Meanwhile, an upper wiring of the semiconductor light-emitting element may be formed after forming the planarization layer and the contact holes, as described with reference to FIG. 22.

As described above, according to the present disclosure, a lift force in a direction opposite to gravity acts on the semiconductor light-emitting element during self-assembly.

Through this, the present disclosure minimizes tailing occurring when a magnetic force acting on the semiconductor light-emitting element is weakened.

1-10. (canceled)

11. A display device comprising:
a substrate; and
a plurality of semiconductor light-emitting elements electrically connected to a wiring electrode,
wherein each of the plurality of semiconductor light-emitting elements is provided with a plurality of recessed portions formed at a side surface thereof, wherein each recessed portion is defined by a plurality of inner walls, and
wherein at least one of the plurality of inner walls of each recessed portion is inclined with respect to a surface of the semiconductor light-emitting element in contact with the substrate.

12. The display device of claim 11, wherein each of the plurality of semiconductor light-emitting elements comprises:
a first and a second conductive electrode;
a first conductive semiconductor layer disposed on the substrate;
an active layer disposed on a portion of the first conductive semiconductor layer; and
a second conductive semiconductor layer disposed on the active layer, and
wherein the first conductive electrode is disposed on a surface of the first conductive semiconductive layer on which the active layer is disposed.

13. The display device of claim 12, wherein each of the recessed portions is formed at a side surface of the first conductive semiconductor layer.

14. The display device of claim 11, wherein each of the semiconductor light-emitting elements comprises:
a first and a second conductive electrode;
a first conductive semiconductor layer disposed on the substrate;
an active layer deposited on the first conductive semiconductor layer; and
a second conductive semiconductor layer disposed on the active layer, and
wherein the first conductive electrode is disposed at a surface of the first conductive electrode facing the substrate, and
wherein the second conductive electrode is disposed at a surface of the second conductive electrode facing away from the substrate.

15. The display device of claim 14, wherein each of the recessed portions is formed across side surfaces of the first conductive semiconductor layer, the active layer, and the second conductive semiconductor layer.

16. The display device of claim 11, wherein each of the recessed portions comprises a plurality of inclined surfaces disposed adjacent to one another.

17. The display device of claim 16, wherein an angle between each inclined surface and the surface of the semiconductor light-emitting element in contact with the substrate increases as a distance from the substrate increases.

18. A method for manufacturing a display device, the method comprising:
manufacturing semiconductor light-emitting elements each having recessed portions at a side surface thereof;
dispersing the semiconductor light-emitting elements in a fluid accommodated in a fluid chamber;
immersing an assembly surface of a substrate in the fluid;
providing a magnet to move in a direction along one side of the substrate to apply a magnetic force for directing the semiconductor light-emitting elements accommodated in the fluid chamber along the direction; and
applying power to a plurality of electrodes disposed on the assembly surface of the substrate to guide the semiconductor light-emitting elements to preset positions on the substrate,
wherein the magnet is rotated while applying the magnetic force to cause rotation of the semiconductor light-emitting elements such that a lift force acts on each of the semiconductor light-emitting elements.

19. The method of claim 18, wherein the manufacturing of the semiconductor light-emitting elements each having recessed portions at a side surface thereof comprises:
forming an epitaxial layer in which a first conductive semiconductor layer, an active layer, and a second conductive semiconductor layer are sequentially deposited on a growth substrate;
depositing a photoresist layer in which a plurality of slits are continuously formed on the second conductive semiconductor layer; and
irradiating light onto the photoresist layer to form semiconductor light-emitting elements each having recessed portions at a side surface thereof, and
wherein the plurality of slits form recessed portions each comprising an inclined surface.

20. The method of claim 18, wherein the manufacturing of the semiconductor light-emitting elements each having recessed portions at a side surface thereof comprises:
forming an epitaxial layer in which a first conductive semiconductor layer, an active layer, and a second conductive semiconductor layer are sequentially deposited on a growth substrate;
etching a portion of the layers deposited on the first conductive semiconductor layer such that a portion of the first conductive semiconductor layer is exposed;
depositing a photoresist layer in which a plurality of slits are continuously formed on the exposed portion of the first conductive semiconductor layer; and
irradiating light onto the photoresist layer such that the recessed portions are formed on a side surface of the first conductive type semiconductor layer, and
wherein the plurality of slits form recessed portions each comprising an inclined surface.
